(19) United States
(12) Patent Application Publication
(10) Pub. No.: US 2012/0310821 A1
(43) Pub. Date: Dec. 6, 2012

(54) SOLAR FIELD CANVAS

(75) Inventors: Yosef ABRAMOWITZ, Jerusalem (IL); Danny LAVIE, Ramat Hasharon (IL)

(73) Assignee: Yosef ABRAMOWITZ, Jerusalem (IL)

(21) Appl. No.: 13/488,473

(22) Filed: Jun. 5, 2012

Related U.S. Application Data
(60) Provisional application No. 61/493,468, filed on Jun. 5, 2011.

(51) Int. Cl. H01L 31/048; G06Q 30/00

(52) U.S. Cl. 705/39; 136/251

(57) ABSTRACT

A solar field made up of a plurality of mutually adjacent solar panels and a substantially horizontal visual display associated aerially with at least a portion of the solar panels. The field may include landscaping which forms at least a portion of the display. The solar panels may include differently colored solar cells arranged to form at least a portion of the display. The field may include a plurality of light emitting elements, coupled to at least a portion of the solar panels and controlled to selectively display a visual image.

This patent application claims the benefit of U.S. Provisional Patent Application No. 61/493,468, filed Jun. 5, 2011

### FIELD AND BACKGROUND OF THE INVENTION

The present invention relates to a solar panel field and, more particularly, to a system and method for providing a system of solar panels in a solar panel field having a distinctive configuration and/or adaptation to provide a particular visual representation.

A photovoltaic module or photovoltaic panel, is a packaged interconnected assembly of solar cells, also known as photovoltaic cells. This type of solar panel can be used as a component of a larger photovoltaic system to generate and supply electricity in commercial and residential applications. Because a single solar panel can only produce a limited amount of power, many installations contain several panels. Solar fields (including any solar energy-gathering technology, not limited to photovoltaic cells as discussed below) are large open areas which have been ‘planted’ with solar panels, which generate energy for local use or integration into the existing electricity grid.

Various other apparatuses are employed in the general art of harnessing solar energy. Solar thermal energy (STE) is an innovative technology for harnessing solar energy for thermal energy (heat). Solar thermal collectors are classified by the United States Energy Information Administration as low-, medium-, or high-temperature collectors. Low-temperature collectors are flat plates generally used to heat swimming pools. Medium-temperature collectors are also usually flat plates but are used for heating water or air for residential and commercial use. High-temperature collectors concentrate sunlight using mirrors or lenses and are generally used for electric power production.

The preceding short discussion regarding solar energy harnessing technologies is in no way intended to be a thorough disposition on the subject matter, but rather a very short summary of some of the main types of technologies used in the art.

Generally, all types of solar fields must have very good sky footage. Sky footage (skf) is the total exposure of any area being considered for a solar panel installation. Solar fields, therefore, provide an excellent visual surface, from a bird's eye view, except for the panels themselves.

It would be highly advantageous to utilize a solar field to provide a visual display, generally visible from an elevated position, made up of a particular physical configuration and/or a preparation of the surface upon which the solar field rests and/or as a multi-panel display upon which an image can be projected or displayed, the latter by manipulating the panels themselves and/or the solar cells therein in such a manner so as to display a desired image.

### DEFINITIONS

The term ‘landscaping’ is used herein to encompass the widest understanding of the concept of topographical arrangement of land. At least the term landscaping includes planting/cultivating grasses, shrubbery, flowers, and any other types of flora according to a pre-conceived design. Furthermore, the term encompasses arrangement of waste material intended for burial, colored rocks, artificial changes in the topography of the ground between and around the solar panels so that the resulting shadows create an encompassing image when viewed from above. Nazca Lines discussed below are included within the scope of this definition.

The term ‘solar panel’ is used generically herein to refer to any type of platform or substrate used in the field of solar energy in the harnessing of solar energy such as the collection and/or conversion of radiant light and heat from the sun into other useful types of energy such as heat and electricity. The term ‘solar field’ is similarly used to generically refer to any type of solar energy harnessing installation including, but not limited to, photovoltaic panels and solar thermal collectors.

The term ‘Solar Canvas™’ or simply ‘solar canvas’ is used herein to refer to a substantially horizontal visual display associated aerially with at least a portion of the solar panels in a solar field. That is to say that the visual display is a result of the combination of a landscape background and solar panels.

‘Associated aerially’ is intended to mean ‘when viewed from above’. So that ‘a visual display associated aerially’ means a visual display that is seen and comprehended when viewed from above or from an elevated vantage point.

### SUMMARY OF THE INVENTION

The current invention includes innovative methods of using solar fields as a background and medium for visual and artistic messages—which are to be viewed from above or at the very least, from an elevated area. Potentially, an observatory installation can created for the public to view the installation from a vantage point. Potentially, a visitor center, restaurant and the like can develop in the vicinity, with the solar field as the point of attraction. Furthermore, visual designs or messages may be displayed on demand (preferably for a price, of course), from the mundane (‘Happy birthday!!’) to the romantic (‘Will you marry me?’) or for advertising purposes and the like. For example, an individual may arrange for a message to be displayed at a certain time during the evening when he and his companion may be dining at the restaurant, for the added romantic effect (see FIG. 4).

One example is for the solar panels to have integrated hardware that allows darkening of photovoltaic/solar cells in a manner controlled by a computing element. A giant picture can be depicted across the entire solar field using the cells in a fashion similar to the way a LCD monitor is made up of pixels or the way mass human formations include large groups of people who are positioned make up different shapes, words or pictures which are usually best viewed from an elevated vantage point.

Alternatively or additionally the panels may be equipped with LEDs which allow for (colored) light projection from the panels, which is best viewed in low-light settings such as at night.

Iconic figures, advertising content, political statements, artistic products and many more can be displayed on the canvas. The pictures can be viewed from a hot air balloon, an elevated place like a mountain or over the Internet on Google Earth™, Google Maps™ and the like.

According to the present invention there is provided a solar field including: (a) a plurality of mutually adjacent solar panels; and (b) a substantially horizontal visual display associated aerially with at least a portion of the solar panels.

According to further features in preferred embodiments of the invention described below the solar panels are selected from the group including: photovoltaic panels and solar thermal collectors.

According to still further features in the described preferred embodiments the substantially horizontal visual display includes landscaping where the landscaping forms at least a portion of the substantially horizontal display.

According to still further features the at least a portion of the solar panels form an incongruent part of the substantially horizontal visual display.

According to still further features the at least a portion of the solar panels form a congruent part of the substantially horizontal visual display.

According to still further features the each solar panel includes a plurality of solar cells.

According to still further features the at least a portion of solar panels include at least two groups of solar cells, wherein each group of solar cells has a respective color distinct from each other group of solar cells.

According to still further features each solar panel includes a plurality of solar cells and wherein the plurality of mutually adjacent solar panels include at least two groups of solar cells, wherein each group of solar cells has a respective color distinct from each other group of solar cells.

According to still further features the landscaping is selected from the group including: floral arrangements, topographical arrangements, arrangement of waste material, rock arrangements, arrangements of exposed soil and arrangements including luminescent material.

According to another embodiment there is provided a solar field including: (a) a plurality of mutually adjacent solar panels; (b) a plurality of light emitting elements, coupled to at least a portion of the plurality of mutually adjacent solar panels; and (c) a mechanism for selectively changing a brightness of each light emitting element to display a visual display.

According to further features the light emitting elements are selected from the group including: Light Emitting Diodes (LEDs), florescent lights, halogen lights, neon lights and incandescent lights.

According to another embodiment there is provided a method for doing business including the steps of: (a) installing a solar field including a plurality of mutually adjacent solar panels; (b) effecting a substantially horizontal visual display associated aerially with at least a portion of the solar panels; and (c) charging a fee for the effecting of the substantially visual display.

According to further features the effecting the substantially horizontal display includes at least one activity selected from the group including: (i) selectively changing a brightness of at least a portion of a plurality of light emitting elements coupled to at least a portion of the plurality of mutually adjacent solar panels, (ii) landscaping about the plurality of mutually adjacent solar panels, wherein the landscaping forms at least a portion of the substantially horizontal display, and (iii) installing at least two groups of solar cells, in the plurality of solar panels, wherein each group of solar cells has a respective color distinct from each other group of solar cells.

According to still further features the effecting of the substantially horizontal visual display is triggered by an event selected from the group including: receiving an SMS message, receiving an electronic input, receiving work request.

### BRIEF DESCRIPTION OF THE DRAWINGS

Various embodiments are herein described, by way of example only, with reference to the accompanying drawings, wherein:

FIG. 1A (prior art) is a field with an image;

FIG. 1B (prior art) is a solar field;

FIG. 1C is an exemplary embodiment of the inventive combination of FIG. 1A and FIG. 1B;

FIG. 2 is an exemplary embodiment of a solar field combined with a landscaped image;

FIG. 3A-B are an exemplary embodiment of a solar field wherein the solar panels create a portion of the desired image and the landscaped area completes the image;

FIG. 4 is an exemplary embodiment of a solar field capable of depicting an image by controlling the lighting of LEDs in or on the solar panels;

FIG. 5 is an exemplary embodiment of a solar field including two differently colored groups of solar panels arranged to depict a given image;

FIG. 6 is a further exemplary embodiment of a solar field having two differently colored groups of solar panels arranged to depict a given image.

### DESCRIPTION OF THE PREFERRED EMBODIMENTS

The principles and operation of a innovative solar field according to the present invention may be better understood with reference to the drawings and the accompanying description.

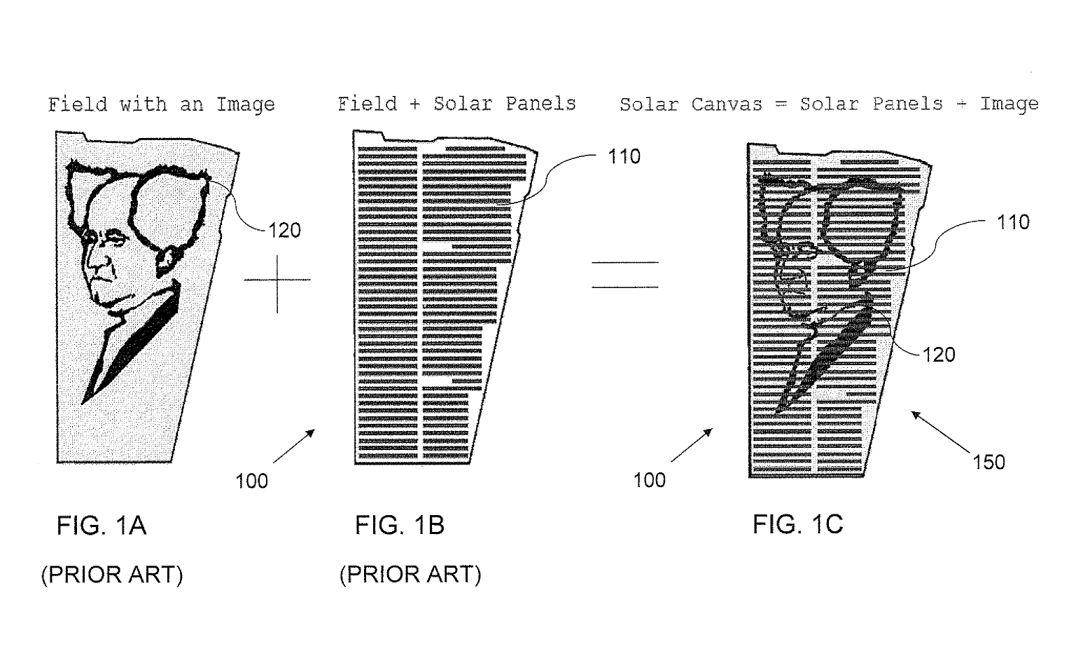

Referring now to the drawings, FIG. 1 illustrate the basic concept of the invention whereby there is produced a landscaped image 120 (FIG. 1A) on the ground and a solar field 100 (FIG. 1B) including rows of solar panels 110 which together are viewed aerially to produce the visual effect termed herein as a ‘solar canvas’ 150 (FIG. 1C).

A number of options are envisioned: Low-tech physical mediums in collaboration with the panels, high-tech/digital images and designer formations.

Low-Tech Medium

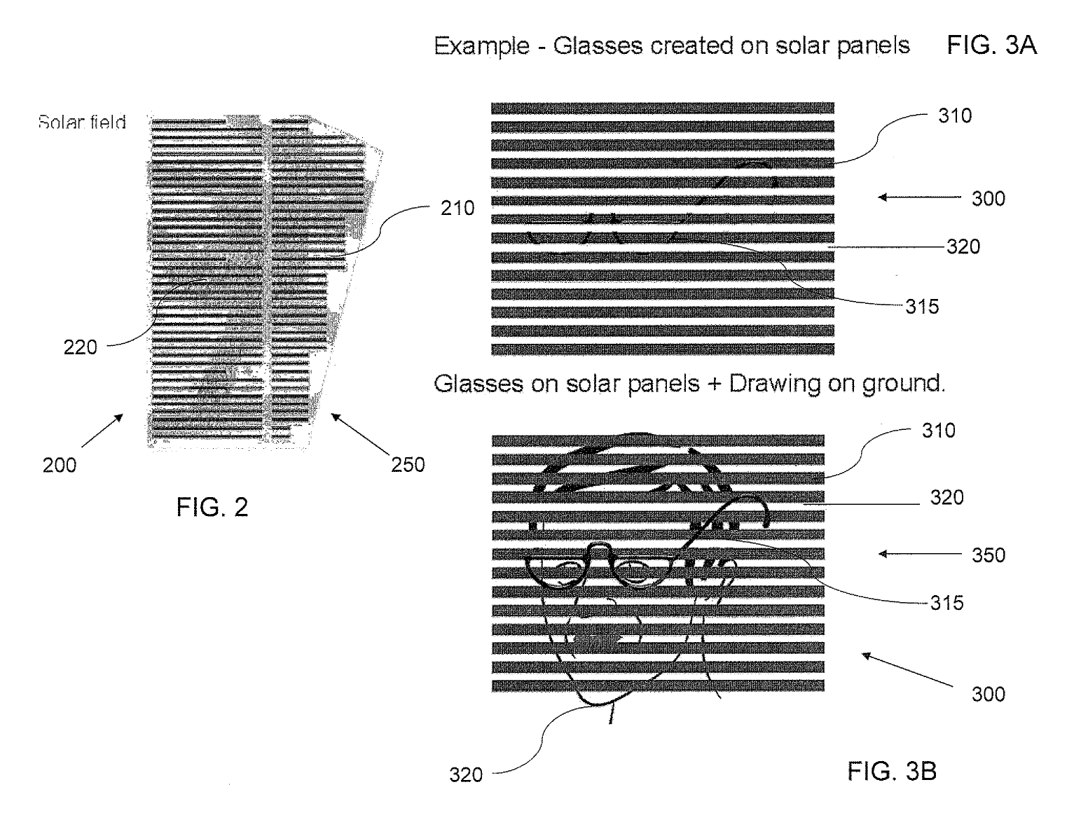

FIG. 2 is an exemplary embodiment of a solar field 200 combined with a landscaped image 220. Referring to the embodiment depicted in FIG. 2, the setting of the solar field presents itself as a variable background (landscaped earth) with a substantially constant medium (the solar panels).

In the currently depicted embodiment, the ground about the panels (i.e. below the panels, between the panel and around the panels) can be decorated in such a manner that when viewed from above, displays a visual image (here the panels are either complimentary to the visuals or are simply ignored).

Some exemplary decorative mediums may include floral formations, waste material intended for burial, colored rocks, artificial changes in the topography of the ground between and around the solar panels so that the resulting shadows create an encompassing image when viewed from above. Other materials can similarly help create images. Indentations in the ground, similar to the Nazca Lines, can be used to create a generally static effect. The Nazca Lines were made by removing the reddish-brown iron oxide-coated pebbles that cover the surface of the Nazca desert. With the gravel removed, the light-colored earth beneath shows in lines of sharply contrasting color and tone. Similar techniques can potentially be utilized in the current invention, either incorporating panels artistically, or ignoring them. In short, the solar field is used as a static or dynamic medium for creating geoglyphs.

In some solar fields, the panels are mounted on fixed racks—where they are immobile, but usually mounted at a latitude-dependent tilt. Other fields include Solar Trackers which are mobile mounts that track the movement of the sun across the sky, thereby increasing the amount of energy produced. Both types of solar fields can be used in the immediate invention. When creating a visual/image using a fixed-rack solar field as the ‘canvas’, the visual, in some instances, may only be optimally be viewed from one particular angle. Generally the available viewing perspectives are: the front (the sun-facing side of the solar panel), from above, or from the back. Of course, the same may be true for tracking racks, but generally to a lesser degree.

FIG. 2 depicts a solar field 200 with the image 220 of a bird created by planting some type of vegetation (e.g. grass or corn) in a pattern that can be viewed aerially (or from some other vantage point, most likely some other elevated vantage point, for best results). Generally, where vegetation or some other form of landscaping is employed, the images or solar canvas 250 can best be viewed during the day.

On the other hand, other materials can be employed, including, for example, phosphorus compounds, that have properties that allow them to glow in the dark. Thus, even low-tech designs can be visible at night. Other artificial lighting may alternatively or additionally be incorporated to create a visual which is visible both day and night.

Another possible configuration is shown in FIGS. 3A and 3B. FIGS. 3A-B depict an exemplary embodiment of a solar field whereby the solar panels 310 create a portion of the desired image 315 and the landscaped area 320b completes the image 350. FIG. 3A depicts the solar field 300 which includes solar panels that have certain solar cells with a different lightness (e.g. darker than the rest of the cells) without any landscaping background of note. The horizontal lines represent the solar panels 310 of the solar field 300. A portion of the solar field includes solar panels which have solar cells of a different lightness or color to the rest of the solar panels, so that when viewed together produce a partial image, depicted here as a pair of glasses 315. The background 320a is depicted here as ‘empty’.

Referring to FIG. 3B, the figure depicts a compound image made up partially from darkened solar cells 315 and partially from a background image 320b. Landscaping 320b about the solar panels is designed to both complete the partial image (i.e. fill in the discontinuous lines of the glasses) as well as add a supplementary image, in this case a face 320b. The advantage of this configuration is that while the partial image formed by the darkened solar cells 315 (i.e. the glasses) is substantially permanent, the design of the landscaped background 320b can be changed periodically. For example, for 6 months of the year the background image could be of Alexandre-Edmond Becquerel (who is attributed to have discovered, at age 19, the photovoltaic effect) while the last 6 months of the year the background image could be of Steve Jobs, as a tribute to his various gadgets, designs and innovations that have shaped the look of modern Western society in recent years. Alternatively, the visual images may be sponsored by an advertiser or other interested party. Such a sponsorship would help offset initial layout and/or overhead cost—making the solar field even more cost effective.

Of course, the solar cells that make up the partial image may in fact be lighter (as opposed to darker) than the rest of the solar cells in the solar panels. Alternatively, the cells may different colors. Recent research in the field has produced various methods and compounds that can be use to coat the cells with various colors while still retaining high to very high efficiency of energy conversion. Usually, solar panels have the darkest coating possible without using completely black coating. The darker coating generally affords a higher efficiency of solar radiation collection than lighter coating. Completely black coating, though, makes the cells substantially ineffectual as the light does not penetrate the coating. Therefore, it would be counter-intuitive to use any type of coating other than the most efficient type. In the immediate invention, even though the lighter coated cells may be less efficient, they are employed here for the added purpose of creating a specific aerially associated image or a portion thereof.

High-Tech Mediums

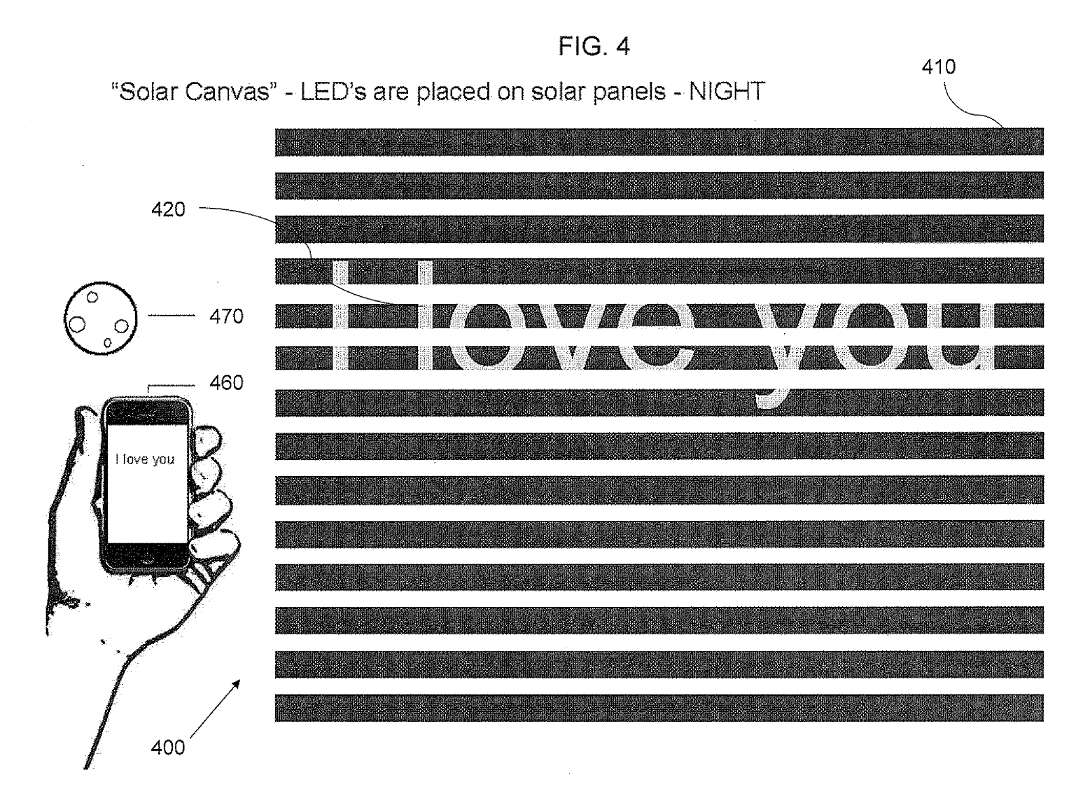

Yet another configuration is shown in FIG. 4. FIG. 4 depicts an exemplary embodiment of a solar field capable of projecting an image by controlling the lighting of LEDs in or on the solar panels of a solar field.

A solar field, which is by definition inactive at night (at least from the point of view of collection), can now be used as a huge multi-paneled screen at night. Colored LEDs, strategic lighting and other technologies can be employed to display visuals on the solar panels themselves and/or on the surrounding ground that can be viewed (primarily) at night.

In order to display digitally created/enhanced images on the solar panels, it is necessary to utilize computing methods, hardware, firmware and software as are well known in the art, although never before used in conjunction with solar panels in solar fields. FIG. 4 depicts an exemplary scenario whereby a computing system controls numerous light sources, such as LEDs, to light up on demand. In the Figure, the control system (not shown) is responsive to SMS messages (and potentially other types of input) sent to the system. Smart-phone 460 has a message “I love you” depicted on the screen. The message is relayed to the control system via some wireless (or even wired) means (email, SMS afforded by Wi-Fi or cellular connectivity and the like; alternatively the information can be entered via a keyboard or other similar input device) and displayed on the solar panels 410 of the solar field 400. The resulting image 415 is achieved by a portion of the LEDs on the solar panels lighting up (possibly even displaying various colors) so as to display the message sent to the system from the smart-phone 460. Ideally, the aforementioned method and system is optimally used at night, as alluded to by the depiction of a moon 470 in the Figure. Therefore, the background landscaping 420 is substantially inconsequential, as it cannot be seen at night without additional artificial lighting. The service provided by the system can be paid for as a surcharge for the SMS message sent or some other equally efficient financial arrangement.

One further envisioned embodiment includes using at least a portion of closely grouped solar panel to display still, or even moving, images in a fashion similar to the giant digital billboards which are commonly found in city centers such as New York's Time Square. The use of a solar field or solar panels as a screen or display platform (i.e. with added LEDs) is counter-intuitive as solar thermal collector are generally positioned on top of building and considered to be an eyesore whereas photovoltaic solar field and other solar fields are generally located in arid and barren areas which are particularly suited for solar collection but not for general habitation (e.g. the Majovie Desert, the Negev Desert etc.). This problem can be overcome by creating a visiting center or educational center to attract the visitors. Alternatively the solar field can be situated along a flight path so as to be viewed from aircraft flying overhead. With the solar field canvas situated is a substantially visible position (and viable for use at night as well)—it would be worthwhile for advertisers or other sponsors to pay for the creation, maintenance and/or activation/projection of an image of their choosing.

Designer Formations

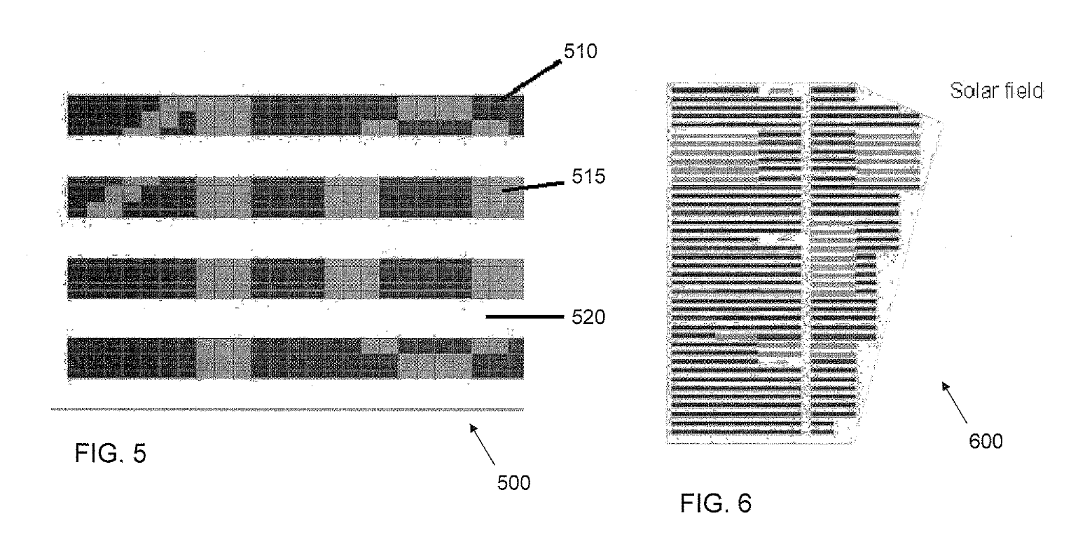

Yet another configuration is shown in FIGS. 5 and 6. Of course, a solar field can be arranged in made-to-order designs when installed. Potentially, to increase the allure of buying a solar field, or renting space for one to be installed, the field may be offered in a specific design. Exemplarily, installing the solar field in the design of an iconic figure, such as Madonna, may have some added allure to some people. FIG. 5 depicts an exemplary embodiment of a solar field including two differently colored groups of solar panels arranged to depict a given image. FIG. 6 depicts a further exemplary embodiment of a solar field having two differently colored groups of solar panels arranged to depict a given image.

In FIG. 5, solar cells 510 are darker than solar cells 515 in solar field 500. The purposeful placement of the different colored cells provides a desired aerially viewed image. Here the landscape background 520 is substantially inconsequential, and the human eye is able to comprehend the image even when part of the image is missing. When viewed from a significant height, such as an airplane, the landscape may not even be visible.

Referring now to FIG. 6, solar field 600 is made up from differently colored solar panels, or potentially, solar panels with differently colored solar cells. The resulting image is an approximation of a face. Here, the landscape/background is inconsequential, not adding any details to the overall image.

In summary, the unifying concept of the invention is the cultivation of solar fields, through various methods, for purposes other than energy conversion, in addition to the main purpose of energy conversion. These methods may be high-tech, middle-tech, low-tech or a combination of some or all of the aforementioned. The solar panels themselves may be fixed-rack, or solar tracking. Any digital, visual enhancing technology may be incorporated into the design of the solar panels, or added on to existing solar panels. The function of the digital/visual components may be controlled by incorporated micro-controllers as well as external computing units, controlling the overall field. Physical material and/or landscaping (topographical changes or botanical arrangements) may be used exclusively with, or in addition to, specialized lighting features and potentially in combination with digital enhancements.

While the invention has been described with respect to a limited number of embodiments, it will be appreciated that many variations, modifications and other applications of the invention may be made. Therefore, the claimed invention as recited in the claims that follow is not limited to the embodiments described herein.

What is claimed is:

1. A solar field comprising:
(a) a plurality of mutually adjacent solar panels; and
(b) a substantially horizontal visual display associated aerially with at least a portion of said solar panels.

2. The solar field of claim 1, wherein said solar panels are selected from the group including: photovoltaic panels and solar thermal collectors.

3. The solar field of claim 1, wherein said substantially horizontal visual display includes landscaping and wherein said landscaping forms at least a portion of said substantially horizontal display.

4. The solar field of claim 3, wherein said at least a portion of said solar panels form an incongruent part of said substantially horizontal visual display.

5. The solar field of claim 3, wherein said at least a portion of said solar panels form a congruent part of said substantially horizontal visual display.

6. The solar field of claim 5, wherein each said solar panel includes a plurality of solar cells.

7. The solar field of claim 6, wherein said at least a portion of said solar panels include at least two groups of said solar cells, wherein each said group of said solar cells has a respective color distinct from each other said group of said solar cells.

8. The solar field of claim 1, wherein each said solar panel includes a plurality of solar cells and wherein said plurality of mutually adjacent solar panels include at least two groups of said solar cells, wherein each said group of said solar cells has a respective color distinct from each other said group of said solar cells.

9. The solar field of claim 3, wherein said landscaping is selected from the group including: floral arrangements, topographical arrangements, arrangement of waste material, rock arrangements, arrangements of exposed soil and arrangements including luminescent material.

10. A solar field comprising:
(a) a plurality of mutually adjacent solar panels;
(b) a plurality of light emitting elements, coupled to at least a portion of said plurality of mutually adjacent solar panels; and
(c) a mechanism for selectively changing a brightness of each said light emitting element to display a visual display.

11. The solar field of claim 1, wherein said light emitting elements are selected from the group including: Light Emitting Diodes (LEDs), florescent lights, halogen lights, neon lights, and incandescent lights.

12. A method for doing business comprising the steps of:
(a) installing a solar field including a plurality of mutually adjacent solar panels;
(b) effecting a substantially horizontal visual display associated aerially with at least a portion of said solar panels; and
(c) charging a fee for said effecting of said substantially visual display.

13. The method of claim 12, wherein said effecting said substantially horizontal display includes at least one activity selected from the group including:
(i) selectively changing a brightness of at least a portion of a plurality of light emitting elements coupled to at least a portion of said plurality of mutually adjacent solar panels,
(ii) landscaping about said plurality of mutually adjacent solar panels, wherein said landscaping forms at least a portion of said substantially horizontal display,
(iii) installing at least two groups of solar cells, in said plurality of solar panels, wherein each said group of solar cells has a respective color distinct from each other said group of solar cells.

14. The method of claim 12, wherein said effecting of said substantially horizontal visual display is triggered by an event selected from the group including: receiving an SMS message, receiving an electronic input, receiving work request.
